(19) United States
(12) Patent Application Publication
(10) Pub. No.: US 2025/0048898 A1
(43) Pub. Date: Feb. 6, 2025

(54) ORGANIC LIGHT EMITTING DISPLAY APPARATUS

(71) Applicant: LG DISPLAY CO., LTD., Seoul (KR)

(72) Inventors: Jungeun LEE, Paju-si (KR); HwanKeon LEE, Paju-si (KR); Hyunseok GO, Paju-si (KR)

(73) Assignee: LG DISPLAY CO., LTD., Seoul (KR)

(21) Appl. No.: 18/679,015

(22) Filed: May 30, 2024

(30) Foreign Application Priority Data
Jul. 31, 2023 (KR) 10-2023-0100124

(51) Int. Cl. H10K 59/80; G06F 3/041; H10K 59/38; H10K 59/40

(52) U.S. Cl. CPC H10K 59/879; H10K 59/38; H10K 59/40; H10K 59/8792; G06F 3/0412

(57) ABSTRACT

An organic light emitting display apparatus includes a substrate; a plurality of organic light emitting elements disposed on the substrate; an optical control layer disposed on the plurality of organic light emitting elements; and a light guide member on the optical control layer; wherein the optical control layer includes a black matrix disposed at a boundary of adjacent organic light emitting elements among the plurality of organic light emitting elements; and wherein the light guide member includes a plurality of lens patterns having an irregular arrangement structure and a first refractive index; and a refractive layer disposed on the plurality of lens patterns and having a second refractive index different from the first refractive index.

### CROSS-REFERENCE TO RELATED APPLICATION

This application claims the priority of the Korean Patent Application No. 10-2023-0100124 filed on Jul. 31, 2023, which is hereby incorporated by reference in its entirety.

### BACKGROUND

### Field of the Disclosure

The present disclosure relates to an organic light emitting display apparatus capable of reducing reflectance by external light while increasing internal light extraction efficiency.

### Description of the Background

As the information society develops, interest in and demand for display devices for displaying images are increasing in various forms, and the display field has been rapidly developed, and in response, various lightweight and thin flat panel display devices have been developed and attracting attention. In recent years, display devices such as liquid crystal display devices and organic light-emitting display devices are being used.

The organic light emitting display apparatus is a self-emitting display device that displays an image on the display panel through the emission of an organic light emitting layer interposed between two electrodes, so unlike the liquid crystal display device, it does not require a separate light source such as a backlight unit, so it may be manufactured in a lightweight and thin manner. In addition, the organic light emitting display apparatus is attracting attention as a next-generation display device because it is advantageous in terms of power consumption by driving low voltage and has excellent color implementation, response speed, viewing angle, and contrast ratio.

Organic light-emitting display devices express images as internal light comes out of the display device, and research is continuing to increase the efficiency of internal light.

In addition, research is continuously being conducted on organic light emitting display apparatuses to prevent rainbow mura phenomenon by light reflected from the display device when a polarizing plate is not used, or to implement low reflectance without using a polarizing plate.

### SUMMARY

Accordingly, the present disclosure is directed to an organic light emitting display apparatus that substantially obviates one or more of problems due to limitations and disadvantages described above.

More specifically, the present disclosure is to provide an organic light emitting display apparatus capable of improving light extraction efficiency of light emitted from an emission layer.

The present disclosure is also to provide an organic light emitting display apparatus including a light guide member capable of minimizing or reducing the occurrence of a rainbow mura phenomenon caused by reflection of external light.

Further, the present disclosure is to provide an organic light emitting display apparatus capable of minimizing or reducing the occurrence of a spark phenomenon caused by a lens pattern.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, an organic light emitting display apparatus includes a substrate; a plurality of organic light emitting elements disposed on the substrate; an optical control layer disposed on the plurality of organic light emitting elements; and a light guide member on the optical control layer; wherein the optical control layer includes a black matrix disposed at a boundary of adjacent organic light emitting elements among the plurality of organic light emitting elements; and wherein the light guide member includes a plurality of lens patterns having an irregular arrangement structure and a first refractive index; and a refractive layer disposed on the plurality of lens patterns and having a second refractive index different from the first refractive index.

In another aspect of the present disclosure, an organic light emitting display apparatus includes a substrate including a plurality of sub-pixels; a plurality of organic light emitting elements disposed in the plurality of sub-pixels; a black matrix disposed between adjacent organic light emitting elements of the plurality of organic light emitting elements; a plurality of lens patterns having a first refractive index and having a shape with an irregularity enough to reduce an intensity of a diffraction dispersion spectrum generated by the plurality of organic light emitting elements or redisperse the diffraction dispersion spectrum; and a refractive layer disposed on the plurality of lens patterns and having a second refractive index greater than the first refractive index, wherein each lens pattern has a diameter greater than a width of each sub-pixel.

The optical control layer may be a color filter layer.

The color filter layer may include a plurality of color filters having different colors, and the black matrix may be disposed between the color filters adjacent to each other.

The light guide member may contact the optical control layer.

The plurality of lens patterns may be formed by an inkjet printing method.

A distance between an upper surface of the black matrix and a lower surface of the light guide member may be greater than 0 and less than or equal to 15 μm.

The substrate may include a plurality of sub-pixels, and a diameter of each of the plurality of lens patterns may be greater than a width of the plurality of sub-pixels.

When the ratio of the height to the diameter of each of the plurality of lens patterns is referred to as the height ratio, the average height ratio of the plurality of lens patterns may be less than 30%.
when the ratio of the height to the diameter of each of the plurality of lens patterns is referred to as the height ratio, the plurality of lens patterns having a height ratio of 50% or more may be 10 to 30% based on the total of the plurality of lens patterns.

The difference between the first refractive index and the second refractive index may range from 0.05 to 0.40.

At least portion of the plurality of lens patterns are arranged to have different diameters or different pitches.

The plurality of lens patterns may have a bottom surface and a convex surface extending from an edge of the bottom surface and having a predetermined curvature.

A planarization layer disposed between the optical control layer and the light guide member may be further included.

A touch electrode disposed between the organic light emitting element and the optical control layer may be further included.

The optical control layer may be a reflectance control layer.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will be more clearly understood from the following detailed description taken in conjunction with the accompanying drawings, in which:

FIG. 1 is a diagram for describing an organic light emitting display apparatus according to an aspect of the present disclosure.

FIG. 2 is a plan view illustrating a planar structure of the pixel shown in FIG. 1.

FIG. 3 is a cross-sectional view taken along line I-I′ of FIG. 2.

FIG. 4 is a diagram illustrating a light guide member according to an aspect of the present disclosure.

FIG. 5 is a cross-sectional view taken along line II-II′ of FIG. 4.

FIG. 6 is a cross-sectional view of a pixel according to another aspect of the present disclosure.

FIG. 7 is a cross-sectional view of a pixel according to another aspect of the present disclosure.

FIG. 8 is a cross-sectional view of a pixel according to another aspect of the present disclosure.

FIG. 9 is a cross-sectional view of a pixel according to another aspect of the present disclosure.

FIG. 10A is a diagram illustrating a sparkle phenomenon of an organic light emitting display apparatus according to a comparative example.

FIG. 10B is a diagram illustrating a sparkle phenomenon of an organic light emitting display apparatus according to a comparative example.

FIG. 10C is a diagram illustrating a sparkle phenomenon of an organic light emitting display apparatus according to an aspect of the present disclosure.

### DETAILED DESCRIPTION

Advantages and features of the present disclosure and implementation methods thereof will be clarified through following aspects described with reference to the accompanying drawings. The present disclosure may, however, be embodied in different forms and should not be construed as limited to the aspects set forth herein. Rather, these aspects are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing aspects of the present disclosure are merely an example and thus, the present disclosure is not limited to the illustrated details. Like reference numerals refer to like elements throughout the disclosure. In the following description, when the detailed description of the relevant known function or configuration is determined to unnecessarily obscure the important point of the present disclosure, the detailed description will be omitted.

In a case where ‘comprise’, ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other and may be variously inter-operated with each other and driven technically as those skilled in the art may sufficiently understand. The aspects of the present disclosure may be carried out independently from each other or may be carried out together in a co-dependent relationship.

In the addition of reference numerals to the components of each drawing describing aspects of the present disclosure, the same components may have the same sign as may be displayed on the other drawings.

In the aspects of the present disclosure, a source electrode and a drain electrode are distinguished for convenience of description, and the source electrode and the drain electrode may be interchanged. The source electrode may be the drain electrode and vice versa. In addition, the source electrode of any one aspect may be a drain electrode in another aspect, and the drain electrode of any one aspect may be a source electrode in another aspect.

In some aspects of the present disclosure, for convenience of description, a source area is distinguished from a source electrode, and a drain area is distinguished from a drain electrode, but aspects of the present disclosure are not limited thereto. The source area may be the source electrode, and the drain area may be the drain electrode. In addition, the source area may be the drain electrode, and the drain area may be the source electrode.

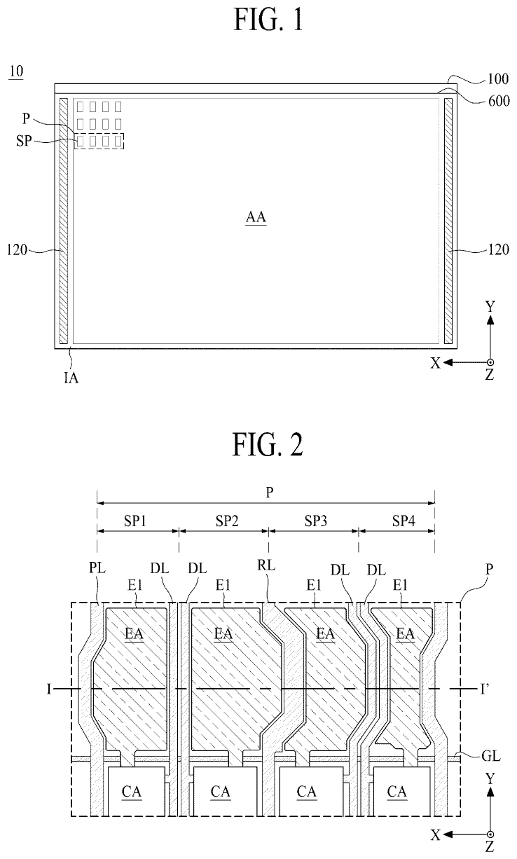

FIG. 1 is a diagram for describing an organic light emitting display apparatus according to an aspect of the present disclosure.

Referring to FIG. 1, an organic light emitting display apparatus according to an aspect of the present disclosure may include a display panel 10 including a substrate 100 and a counter substrate 600 bonded to each other.

The substrate 100 includes a thin film transistor and may be a transparent glass substrate or a transparent plastic substrate. The substrate 100 may include a display area AA and a non-display area IA.

The display area AA is an area in which an image is displayed, and may be a pixel array area, an active area, a pixel array unit, a display unit, or a screen. The display area AA may include a plurality of pixels P.

A plurality of pixels P may be disposed along each of the first direction X and the second direction Y crossing the first direction X.

Each of the plurality of pixels P may include a plurality of adjacent sub-pixels SP. For example, a plurality of sub-pixels SP may constitute a plurality of pixels P. For example, the first direction X may be a first length direction, a long side length direction, a horizontal direction, or a first horizontal direction of the substrate 100. For example, the second direction Y may be a second length direction, a short side length direction, a vertical direction, a second horizontal direction, or a vertical direction of the substrate 100.

The non-display area IA is an area in which no image is displayed, and may be a peripheral circuit area, a signal supply area, an inactive area, or a bezel area. The non-display area IA may be configured to surround the display area AA. The display panel 10 or the substrate 100 may further include a peripheral circuit unit 120 disposed in the non-display area IA. The peripheral circuit unit 120 may include a gate driving circuit connected to the plurality of sub-pixels SP.

The counter substrate 600 may be configured to overlap the display area AA. The counter substrate 600 may be bonded to face the substrate 100 through an adhesive member (or a transparent adhesive), or may be disposed in a manner in which an organic material or an inorganic material is stacked on the substrate 100. The counter substrate 600 may be an upper substrate, a second substrate, or an encapsulation substrate, and may correspond to encapsulating the substrate 100.

FIG. 2 is a plan view illustrating a planar structure of the pixel shown in FIG. 1.

Referring to FIGS. 1 and 2, in the organic light emitting display apparatus or the display panel 10 according to an aspect of the present disclosure, each of the plurality of pixels P may include four sub-pixels SP1 to SP4.

Each of a plurality of pixels P according to an aspect may include first to fourth sub-pixels SP1 to SP4 adjacent to each other along the first direction X. For example, each of a plurality of pixels P may include a red first sub-pixel SP1, a white second sub-pixel SP2, a green third sub-pixel SP3, and a blue fourth sub-pixel SP4, but an aspect of the present disclosure is not limited thereto. Each of the first to fourth sub-pixels SP1 to SP4 may have different sizes (or areas).

Each of the first to fourth sub-pixels SP1 to SP4 may include a light emitting area EA and a circuit area CA.

The light emitting area EA may be disposed on one side (or upper side) of the sub-pixel area. The light emitting area EA of each of the first to fourth sub-pixels SP1 to SP4 may have different sizes (or areas). For example, the light emitting area EA may be an open area or a light emitting area.

The light emitting area EA of each of the first to fourth subpixels SP1 to SP4 may be configured to have different sizes (or areas). In an aspect, in the light emitting area EA of each of the first to fourth subpixels SP1 to SP4, the light emitting area EA of the second subpixel SP2 may have the largest size, the light emitting area EA of the fourth subpixel SP4 may have the smallest size, and the light emitting area EA of the first subpixel SP1 may be smaller than the light emitting area EA of the second subpixel SP2, and may have a size larger than the light emitting area EA of each of the third and fourth subpixels SP3 and SP4. In addition, the light emitting area E3 of the third subpixel SP3 may have a size larger than the light emitting area EA of the fourth subpixel SP4. However, an aspect of the present disclosure is not limited thereto.

The circuit area CA of each of the first to fourth sub-pixels SP1 to SP4 may be spatially separated from the light emitting area EA within the sub-pixel area SPA. For example, the circuit area CA may be disposed on the other side (or lower side) of the sub-pixel area, but is not limited thereto. For example, at least a portion of the circuit area CA may overlap the light emitting area EA within the sub-pixel area SPA. For example, the circuit area CA may overlap the entire light emitting area EA or may be disposed under the light emitting area EA within the sub-pixel area. For example, the circuit area CA may be a non-emission area or a non-opening area.

Each of a plurality of pixels P according to another aspect may further include a light transmitting portion disposed around at least one of the light emitting area EA and the circuit area CA of each of the first to fourth subpixels SP1 to SP4. For example, each of a plurality of pixels P may include a light emitting area EA for each pixel corresponding to each of the plurality of subpixels SP1 to SP4, and a light transmitting portion disposed around each of the plurality of subpixels SP, and in this case, the organic light emitting display apparatus may implement a transparent organic light emitting display apparatus due to light transmission of the light transmitting portion.

Two data lines DL extending along the second direction Y may be disposed in parallel between the first sub-pixel SP1 and the second sub-pixel SP2, and between the third sub-pixel SP3 and the fourth sub-pixel SP4, respectively. A gate line GL extending along the first direction X may be disposed between the light emitting area EA and the circuit area CA of each of the first to fourth sub-pixels SP1 to SP4. A pixel power line PL extending along the second direction Y may be disposed at one side of the first sub-pixel SP1 or the fourth sub-pixel SP4. A reference line RL extending along the second direction Y may be disposed between the second sub-pixel SP2 and the third sub-pixel SP3. The reference line RL may be used as a sensing line for externally sensing a characteristic change of a driving thin film transistor disposed in the circuit area CA and/or a characteristic change of a light emitting element layer in a sensing driving mode of the pixel P.

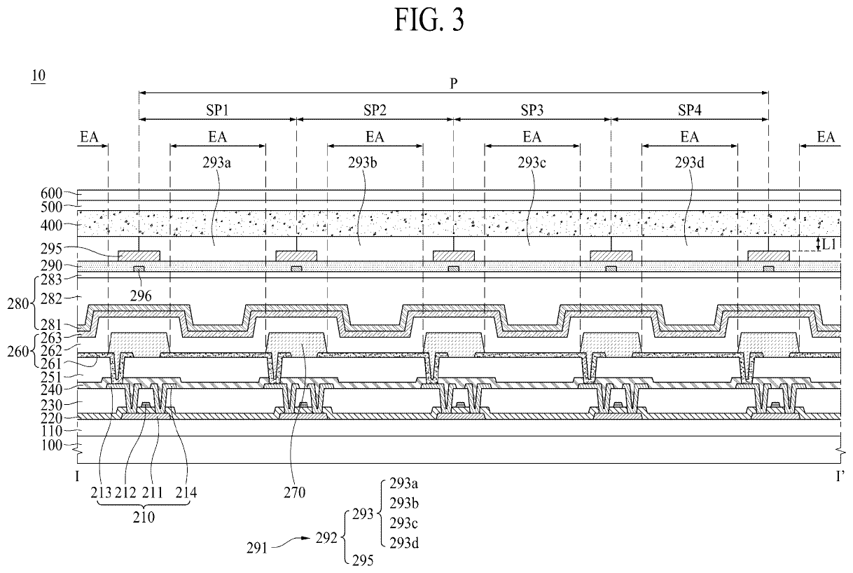

FIG. 3 is a cross-sectional view taken along line I-I′ of FIG. 2.

Referring to FIGS. 2 and 3, the organic light emitting display apparatus according to an aspect of the present disclosure may include a substrate 100 and an opposite substrate 600. For example, the organic light emitting display apparatus or the display panel 10 according to an aspect of the present disclosure may include a substrate 100 and an opposite substrate 600.

The substrate 100 includes a thin film transistor, and may be a first substrate, a base substrate, a lower substrate, a transparent glass substrate, a transparent plastic substrate, or a base member.

Referring to FIG. 3, a buffer layer 110 may be disposed on the substrate 100. The buffer layer 110 may be disposed on the entire first surface (or front surface) of the substrate 100. The buffer layer 110 may serve to block diffusion of a material contained in the substrate 100 into the transistor layer during a high-temperature process during a thin film transistor manufacturing process or may also serve to prevent external moisture or moisture from penetrating toward the organic light emitting element 260. The buffer layer 110 may be formed of a plurality of inorganic layers alternately stacked. For example, the buffer layer 110 may be formed of multiple layers in which one or more inorganic layers among silicon oxide (SiOx), silicon nitride (SiNx), and SION are alternately stacked. The buffer layer 110 may be omitted.

Referring to FIG. 3, the thin film transistors 210 are formed on the buffer layer 110. Each of the thin film transistors 210 includes an active layer 211, a gate electrode 212, a source electrode 213, and a drain electrode 214. Although FIG. 3 illustrates that the thin film transistor 210 is formed by a top gate method in which the gate electrode 212 is disposed on the active layer 211, it should be noted that the present disclosure is not limited thereto. That is, the thin film transistors 210 may be formed by a bottom gate method in which the gate electrode 212 is disposed on a lower portion of the active layer 211 or a double gate method in which the gate electrode 212 is disposed on both an upper portion and a lower portion of the active layer 211.

An active layer 211 is formed on the buffer layer 110. The active layer 211 may be formed of a silicon-based semiconductor material or an oxide-based semiconductor material. A light blocking layer for blocking external light incident on the active layer 211 may be formed between the buffer layer 110 and the active layer 211.

A gate insulating layer 220 may be formed on the active layer 211. The gate insulating layer 220 may be formed of an inorganic layer, for example, a silicon oxide film (SiOx), a silicon nitride film (SiNx), or multiple films thereof.

The gate electrode 212 and the gate line may be formed on the gate insulating layer 220. The gate electrode 212 and the gate line may be formed as a single layer or multiple layers include one of molybdenum (Mo), aluminum (Al), chromium (Cr), gold (Au), titanium (Ti), nickel (Ni), neodymium (Nd), and copper (Cu), or an alloy thereof.

An interlayer insulating layer 230 may be formed on the gate electrode 212 and the gate line. The interlayer insulating layer 230 may be formed of an inorganic layer, for example, a silicon oxide layer (SiOx), a silicon nitride layer (SiNx), or multiple layers thereof.

The source electrode 213, the drain electrode 214, and the data line may be formed on the interlayer insulating layer 230. Each of the source electrode 213 and the drain electrode 214 may be connected to the active layer 211 through a contact hole penetrating the gate insulating layer 220 and the interlayer insulating layer 230. The source electrode 213, the drain electrode 214, and the data line may be formed as a single layer or multiple layers including one of molybdenum (Mo), aluminum (Al), chromium (Cr), gold (Au), titanium (Ti), nickel (Ni), neodymium (Nd), and copper (Cu), or an alloy thereof.

A passivation layer 240 for insulating the thin film transistor 210 may be formed on the source electrode 213, the drain electrode 214, and the data line. The passivation layer 240 may be formed of an inorganic layer, for example, a silicon oxide layer (SiOx), a silicon nitride layer (SiNx), or multiple layers thereof.

The planarization portion 251 for planarizing a step difference due to the thin film transistor 210 may be formed on the passivation layer 240. The planarization portion 251 may be formed of an organic layer such as an acrylic resin, an epoxy resin, a phenolic resin, a polyamide resin, a polyimide resin, or the like.

The organic light emitting element 260 and the bank 270 are formed on the planarization portion 251. The organic light emitting element 260 includes a first electrode 261, an organic light emitting layer 262, and a second electrode 263. The first electrode 261 may be an anode electrode, and the second electrode 263 may be a cathode electrode.

The first electrode 261 may be formed on the planarization portion 251. The first electrode 261 is connected to the source electrode 213 of the thin film transistor 210 through a contact hole penetrating the passivation layer 240 and the planarization portion 251. In the case of the upper light emission method in which light of each of the pixels P is output toward the opposite substrate 600, the first electrode 261 may include a single layer structure or a multilayer structure formed of any one material selected from aluminum (Al), silver (Ag), molybdenum (Mo), gold (Au), magnesium (Mg), calcium (Ca), or barium (Ba).

The bank 270 may be formed on the planarization portion 251 to cover an edge of the first electrode 261 to partition the pixels P. That is, the bank 270 serves as a pixel defining layer defining the pixels P.

Each of the pixels P represents a region in which a first electrode 261 corresponding to an anode electrode, an organic light emitting layer 262, and a second electrode 263 corresponding to a cathode electrode are sequentially stacked to emit light by combining holes from the first electrode 261 and electrons from the second electrode 263 with each other in the organic light emitting layer 262. In this case, the region in which the bank 270 is formed does not emit light and thus may be defined as a non-emission portion.

The bank 270 may be formed of an organic layer such as an acrylic resin, an epoxy resin, a phenolic resin, a polyamide resin, a polyimide resin, or the like.

An organic light emitting layer 262 is formed on the first electrode 261 and the bank 270. The organic light emitting layer 262 is a common layer commonly formed on the pixels P, and may be a white light emitting layer emitting white light. In this case, the organic light emitting layer 262 may be deposited using an open mask having an opening formed over the entire display area.

When the organic emission layer 262 is formed as a common layer emitting white light, the organic emission layer 262 may be formed in a tandem structure of two or more stacks. Each of the stacks may include a hole transporting layer, at least one light emitting layer, and an electron transporting layer.

In addition, a charge generation layer may be formed between the stacks. The charge generation layer may include an n-type charge generation layer which is formed on the n-type charge generation layer which is located adjacent to the lower stack, and a p-type charge generation layer which is formed on the n-type charge generation layer and is located adjacent to the upper stack. The n-type charge generation layer injects electrons into the lower stack, and the p-type charge generation layer injects holes into the upper stack. The n-type charge generation layer may be an organic layer which is doped with an alkali metal such as Li, Na, K, or Cs, or an alkaline earth metal such as Mg, Sr, Ba, or Ra into an organic host material having electron transport capability. The p-type charge generation layer may be an organic layer which is doped with a dopant into an organic host material having hole transport capability.

The second electrode 263 is formed on the organic light emitting layer 262. The second electrode 263 is a common layer commonly formed in the pixels P. The second electrode 263 may be formed of a transparent conductive material (TCO) such as ITO and IZO capable of transmitting light, or a semi-transmissive conductive material such as magnesium (Mg), silver (Ag), and an alloy of magnesium (Mg) and silver (Ag).

The encapsulation layer 280 is disposed on the second electrode 263. The encapsulation layer 280 serves to prevent oxygen or moisture from penetrating into the organic emission layer 262 and the second electrode 263. The encapsulation layer 280 may include at least one inorganic layer. Also, the encapsulation layer 280 may further include at least one inorganic layer to prevent foreign substances from being introduced into the organic emission layer 262 and the second electrode 263. For example, the encapsulation layer 280 may include a first inorganic layer 281, an organic layer 282, and a second inorganic layer 283 as illustrated in FIG. 3.

The first inorganic layer 281 is disposed on the second electrode 263. The first inorganic layer 281 may be formed to cover the second electrode 263.

The organic layer 282 is disposed on the first inorganic layer 281. The organic layer 282 may be formed to have a sufficient thickness to penetrate the first encapsulation layer 280 and the first inorganic layer 281 and prevent the organic light emitting layer 262 and the second electrode 263 from being injected thereinto.

The second inorganic layer 283 is disposed on the organic layer 282. The second inorganic layer 283 may be formed to cover the organic layer 282.

Each of the first inorganic layer 281 and the second inorganic layer 283 may be formed of silicon nitride, aluminum nitride, zirconium nitride, titanium nitride, hafnium nitride, tantalum nitride, silicon oxide, aluminum oxide, or titanium oxide.

Referring to FIG. 3, the organic light emitting display apparatus may include a touch electrode 296 on the organic light emitting element 260. Specifically, the touch electrode 296 may be disposed as a touch sensor for touch sensing. In FIG. 3, a configuration in which the touch electrode 296 is disposed on the second inorganic layer 283 is illustrated.

In this case, the touch electrode 296 may be formed of a metal layer, which is a conductive metal such as copper (Cu), aluminum (Al), molybdenum (Mo), chromium (Cr), gold (Au), titanium (Ti), nickel (Ni), and neodymium (Nd), but is not limited thereto as a single layer or multiple layers.

According to an aspect of the present disclosure, the black matrix 295 and the touch electrode 296 may overlap each other. Specifically, since the black matrix 295 is located in the area where the touch electrode 296 is located, reflection of external light by the touch electrode 296 may be more effectively prevented or suppressed. As a result, visibility of reflection due to external light may be deteriorated.

Referring to FIG. 3, the touch electrode 296 may be disposed in the touch buffer layer 290. In this case, the touch buffer layer 290 may be formed of a plurality of inorganic layers alternately stacked. For example, the touch buffer layer 290 may be formed of multiple layers in which at least one inorganic layer among silicon oxide (SiOx), silicon nitride (SiNx), and SiON is alternately stacked. The touch buffer layer 290 may be omitted.

The organic light emitting display apparatus according to an aspect of the present disclosure may further include an optical control layer 291 disposed on the organic light emitting element 260. Specifically, in FIG. 3, a configuration in which the optical control layer 291 is disposed on the touch electrode 296 is shown.

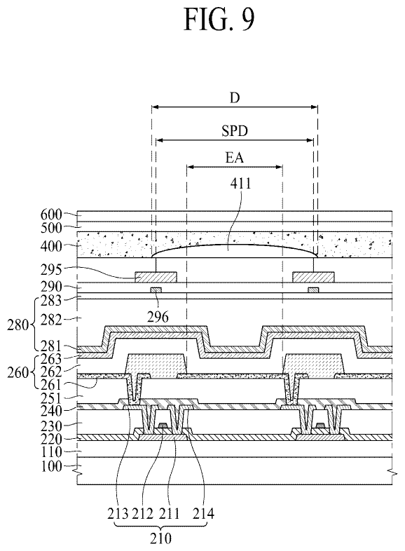

Referring to FIG. 9, According to an embodiment of the present invention, each of the plurality of lens pattern 411 covers a part of each of two adjacent black matrix 295.

Referring to FIG. 9, According to an embodiment of the present invention, each of the plurality of lens pattern 411 covers a part of each of two adjacent touch electrode 296.

According to an aspect of the present disclosure, the optical control layer 291 may be a color filter layer 292. Specifically, the color filter layer 292 includes a plurality of color filters 293 having different colors, and as an example, referring to FIG. 3, a plurality of color filters 293 may include a first color filter 293a, a second color filter 293b, a third color filter 293c, and a fourth color filter 293d.

The color filter 293 may be disposed between the organic light emitting element 260 and the opposite substrate 600 to overlap at least one light emitting area EA. Specifically, the color filter 293 may be disposed between the encapsulation layer 280 and the light guide member 400.

The color filter 293 may have a size wider than the light emitting area EA. For example, an edge portion of the color filter 293 may overlap the bank 270. For example, the color filter 293 may have a size corresponding to each of the subpixels SP1, SP2, SP3, and SP4, and thus light leakage between adjacent subpixels SP may be reduced.

According to an aspect of the present disclosure, the color filter 293 may be configured to transmit a wavelength of a color set in the subpixel SP. For example, as illustrated in FIG. 2, when one pixel P includes the first to fourth subpixels SP2, SP2, SP2, SP3, and SP4, the first to fourth color filters 293a, 293b, 293c, and 293d may include a red color filter provided in the first subpixel SP1, a green color filter provided in the third subpixel SP3, and a blue color filter provided in the fourth subpixel SP4. The second subpixel SP2 may not include a color filter layer or may include a transparent material for step compensation, and thus may emit white light.

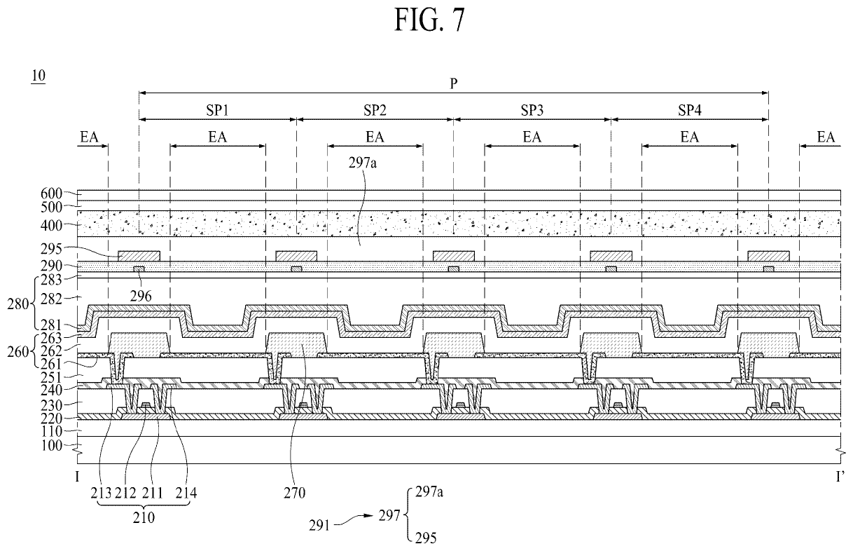

The optical control layer 291 according to an aspect of the present disclosure may further include a black matrix 295. Specifically, referring to FIG. 3, when the optical control layer 291 is referred to as the color filter layer 292, the color filter layer 292 may include a plurality of color filters 293 and a black matrix 295. However, an aspect of the present disclosure is not limited thereto, and the optical control layer 291 may be the reflectance control layer 297 (shown in FIG. 7).

According to an aspect of the present disclosure, the black matrix 295 is disposed at the boundary of a plurality of adjacent organic light emitting elements 260. In this case, the boundary of the organic light emitting element 260 coincides with the boundary of the subpixels SP1, SP2, SP3, and SP4. That is, the black matrix 295 overlaps the boundary of a plurality of adjacent subpixels SP1, SP2, SP3, and SP4. Specifically, the black matrix 295 may be disposed on the same layer as a plurality of color filters 293. For example, referring to FIG. 3, a plurality of color filters 293 and a black matrix 295 may be disposed on the touch buffer layer 290. More specifically, the black matrix 295 is disposed between a plurality of color filters 293 adjacent to each other.

The black matrix 295 may be disposed to overlap the remaining areas except for the emission area EA of each subpixel SP. Specifically, the black matrix 295 may be disposed to correspond to the bank 270.

The organic light emitting display apparatus according to the exemplary configuration of the present disclosure may further include a light guide member 400.

The light guide member 400 may be disposed on the optical control layer 291. Specifically, the light guide member 400 may be disposed on the optical control layer 291 and between the optical control layer 291 and the opposite substrate 600.

According to an aspect of the present disclosure, the light guide member 400 may be coupled to the opposite substrate 600 via an adhesive member 500. For example, the adhesive member 500 may be disposed between the light guide member 400 and the opposite substrate 600.

The light guide member 400 may be configured to improve a rainbow mura (or rainbow stain pattern) pattern due to external reflection in a non-driving or off state of the organic light emitting display apparatus or the display panel 10. For example, when the polarizing plate is not used, a rainbow mura phenomenon may be seen by light reflected from the display device, which may cause display quality of the display device to deteriorate.

According to an aspect of the present disclosure, the light guide member 400 may be configured to diffract and/or scatter external light incident through the opposite substrate 600 from the outside based on the light refraction principle according to the cross-sectional shape having the refractive index difference, or to redisperse (or disperse) the diffraction dispersion spectrum of the reflected light generated by the organic light emitting element 260 or the like. For example, the light guide member 400 may suppress or minimize the occurrence of the radial rainbow mura phenomenon through mixing between adjacent spectra according to the diffraction order of the reflected light by reducing the intensity of the diffraction dispersion spectrum generated by the organic light emitting element 260 or the like, or redisperse the diffraction dispersion spectrum to greatly expand the size of the spectrum.

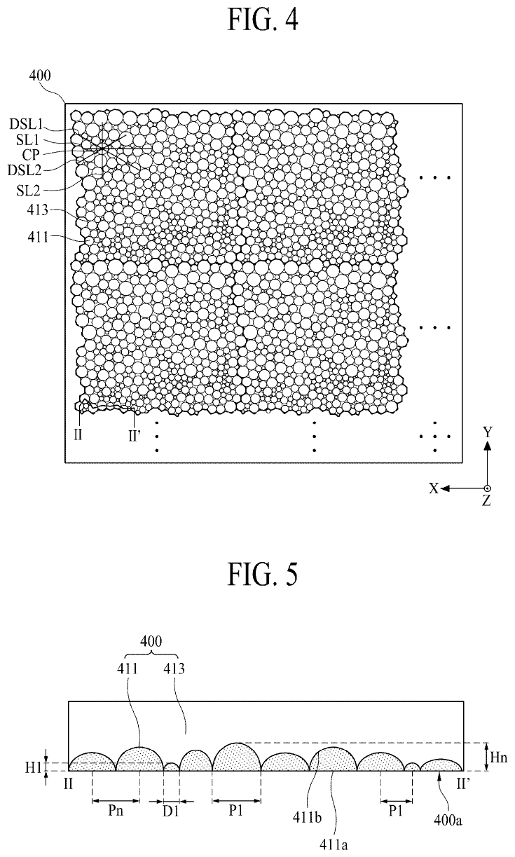

FIG. 4 is a view showing a light guide member according to an aspect of the present disclosure. FIG. 5 is a cross-sectional view taken along line II-II′ of FIG. 4.

Referring to FIGS. 4 and 5, the light guide member 400 may include a plurality of lens patterns 411 having an irregular arrangement structure and a refractive layer 413. Specifically, the refractive layer 413 may be disposed on a plurality of lens patterns 411. More specifically, the refractive layer 413 may be filled in a concave portion (or a valley portion) between a plurality of lens patterns 411.

Each of the plurality of lens patterns 411 may be formed of a material having a first refractive index n1, and the refractive layer 413 may be formed of a material having a second refractive index n2 different from the first refractive index n1 of the plurality of lens patterns 411. For example, the refractive layer 413 may be formed of a material having a refractive index higher than that of each of the plurality of lens patterns 411. More specifically, the difference between the refractive index of the first refractive index n1 and the second refractive index n2 may range from 0.05 to 0.40.

According to an aspect of the present disclosure, when the difference in the refractive index between the first refractive index n1 and the second refractive index n2 is 0.05 to 0.40, the light guide member 400 including the plurality of lens patterns 411 and the refractive layer 413 may suppress or minimize the occurrence of the radial rainbow mura phenomenon through mixing between adjacent spectra according to the diffraction order of the reflected light by reducing the intensity of the diffraction spectrum of the reflected light generated by the organic light emitting element 260 or the like, or redisperse the diffraction dispersion spectrum to greatly expand the size of the spectrum.

On the other hand, when the difference between the refractive index of the first refractive index n1 and the second refractive index n2 is greater than 0.40, the occurrence of rainbow mura due to reflection of external light may be reduced or suppressed, but the material reliability of the plurality of lens patterns 411 and the refractive layer 413 may deteriorate.

In addition, if the difference in refractive index between the first refractive index (n1) and the second refractive index (n2) is less than 0.05, even if the material reliability of the plurality of lens patterns (411) and the refractive layer (413) is secured, there is a problem that rainbow mura occurs due to reflection of external light.

According to an aspect of the present disclosure, a plurality of lens patterns 411 may be formed by an inkjet printing method. Specifically, when a plurality of lens patterns 411 are formed by an inkjet printing method, irregularities (or atypical formation) of the plurality of lens patterns 411 may increase. Due to the increase in irregularities (or atypical formation) with respect to the plurality of lens patterns 411, the light guide member 400 may suppress or minimize the occurrence of the radial rainbow mura phenomenon through mixing between adjacent spectra according to the diffraction order of the reflected light by reducing the intensity of the diffraction spectrum generated by the organic light emitting element 260 or the like, or redisperse the diffraction dispersion spectrum to greatly expand the size of the spectrum.

According to an aspect of the present disclosure, when the ratio of the height H to the diameter D of each of the plurality of lens patterns 411 is the height ratio (H/D), a plurality of lens patterns 411 having the height ratio (H/D) of 50% or more may be 10 to 30% of the total of the plurality of lens patterns 411. In this case, the irregularity (or irregularity) of the plurality of lens patterns 411 may increase, and due to the increase in irregularity (or irregularity) of the plurality of lens patterns 411, the light guide member 400 may suppress or minimize the occurrence of the radial rainbow mura phenomenon through mixing between adjacent spectra according to the diffraction order of the reflected light, by reducing the intensity of the diffraction dispersion spectrum of the reflected light generated by the organic light emitting element 260 or the like, or by redisperse the diffraction dispersion spectrum to greatly expand the size of the spectrum.

On the other hand, when a plurality of lens patterns 411 having a height ratio (H/D) of 50% or more is less than 10% of the total of the plurality of lens patterns 411, irregularity (or atypical formation) of the plurality of lens patterns 411 is reduced, and the light guide member 400 cannot disperse or expand the intensity of the diffraction dispersion spectrum of reflected light generated by the organic light emitting element 260 or the like, resulting in a rainbow mura phenomenon.

In addition, when a plurality of lens patterns 411 having a height ratio (H/D) of 50% or more is greater than 30% of the total of the plurality of lens patterns 411, the plurality of lens patterns 411 having a height ratio (H/D) of 50% or more is excessively increased, and thus the average height ratio (H/D) of the plurality of lens patterns 411 may be excessively increased. As a result, a sparkle phenomenon may occur due to excessive irregularity (or atypical formation) of the plurality of lens patterns 411.

The center portions CP of at least one of a plurality of lens patterns 411 may be spaced apart from at least one of a first straight line SL1, a second straight line SL2, a first diagonal straight line DSL1, and a second diagonal straight line DSL2. For example, among a plurality of lens patterns 411, the pitches P1 to Pn between two adjacent lens patterns may be different from one or more of a first direction X, a second direction Y, and a diagonal direction between the first direction X and the second direction Y. For example, a plurality of lens patterns 411 may be configured to have different pitches P1 to Pn along at least one of a first direction X, a second direction Y, and a diagonal direction between the first direction X and the second direction Y.

According to an aspect of the present disclosure, each of a plurality of lens patterns 411 may have different diameters D1 to Dn within the range of 1 μm to 30 μm. For example, a plurality of lens patterns 411 are connected to each other along at least one of a first direction X, a second direction Y, and a diagonal direction between the first direction X and the second direction Y, and thus may have various diameters D1 to Dn within the range of 1 μm to 30 μm. For example, the first refractive layer consisting of a plurality of lens patterns 411 may have a structure in which a plurality of lens patterns 411 having a relatively small diameter are disposed between a plurality of lens patterns 411 having a relatively large diameter or may be filled.

Each of a plurality of lens patterns 411 may have different heights H1 to Hn. More specifically, each of a plurality of lens patterns 411 may have different heights H1 to Hn from the first surface 400a of the light guide member 400. More specifically, the heights H1 to Hn of each of a plurality of lens patterns 411 may be a distance between the first surface 400a or the bottom surface 411b, and the top surface of the convex surface 411c of the light guide member 400.

According to an aspect of the present disclosure, when a plurality of lens patterns 411 are formed by an inkjet printing method and are configured to have a random arrangement structure over the entire display area of the display panel, a sparkle phenomenon may occur due to irregularities (or atypical formation) of the plurality of lens patterns 411. Here, the sparkle phenomenon may correspond to a phenomenon in which a light portion and a dark portion appear irregularly according to the pitches (P1 to Pn) (or intervals) of the plurality of lens patterns 411, and thus appear like a stain.

According to an aspect of the present disclosure, when the distance between the upper surface of the black matrix 295 and the lower surface of the light guide member 400 is L1, L1 may be greater than 0 and less than or equal to 15 μm.

Specifically, referring to FIG. 9, when L1 is greater than 0 and equal to or less than 15 μm, the diameter D of each of a plurality of lens patterns 411 may be greater than the width SPD of the subpixel SP. When the diameter D of each of a plurality of lens patterns 411 is greater than the width SPD of the subpixel SP, light emitted from the subpixel SP does not pass through a plurality of adjacent lens patterns 411, and as a result, excessive refraction may be prevented, thereby improving a sparkle phenomenon.

On the other hand, if L1 is greater than 0 and less than or equal to 15 μm, and the diameter D of each of the plurality of lens patterns 411 is smaller than the width SPD of the subpixel SP, the valleys of the plurality of lens patterns 411 meet the valleys of other adjacent lens patterns 411 within the subpixel SP, resulting in excessive refraction of light emitted from the subpixel SP, resulting in a sparkle phenomenon.

Also, when L1 is greater than 0 and equal to or less than 15 μm, a plurality of lens patterns 411 may have an average height ratio (H/D) of less than 30%. The average height ratio (H/D) means an average of the height ratios (H/D) of each of a plurality of lens patterns 411. When the plurality of lens patterns 411 have the average height ratio (H/D) of less than 30%, the valleys of the plurality of lens patterns 411 are not deepened, and thus, the refractive angles of the lights emitted from the subpixels SP do not increase in the valleys of the plurality of lens patterns 411. As a result, excessive refraction may be prevented, thereby improving a sparkle phenomenon.

On the other hand, when L1 is greater than 0 and equal to or less than 15 μm, when the plurality of lens patterns 411 have an average height ratio (H/D) greater than 30%, the valleys of the plurality of lens patterns 411 become deeper, and the light emitted from the subpixel SP increases the refractive angle in the valleys of the plurality of lens patterns 411. As a result, the refractive angle of the light emitted from the subpixel SP becomes excessively large, and thus a sparkle phenomenon may occur.

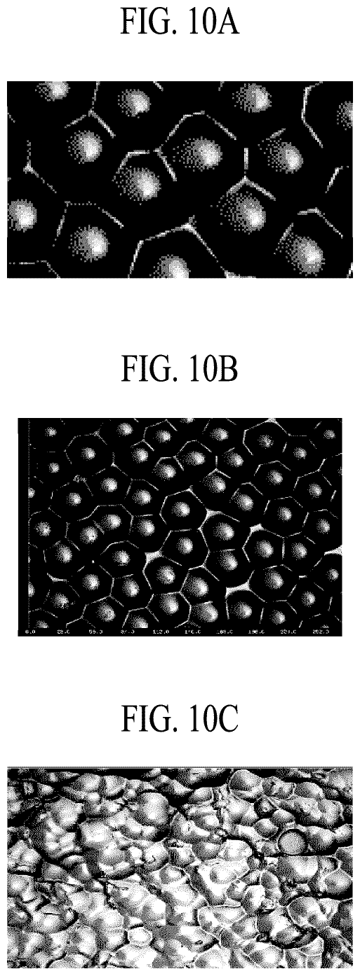

FIG. 10A is a view illustrating a sparkle phenomenon of an organic light emitting diode display according to a comparative example. FIG. 10B is a view illustrating a sparkle phenomenon of an organic light emitting diode display according to a comparative example. FIG. 10C is a view illustrating a sparkle phenomenon of an organic light emitting diode display according to an aspect.

Specifically, FIGS. 10A to 10C are diagrams illustrating a sparkle phenomenon according to a change in the diameter D and average height ratio H/D of each of a plurality of lens patterns 411 when the width SPD of the subpixel SP is 26 μm.

FIG. 10A is a diagram illustrating a sparkle phenomenon when the diameters D1 to Dn of a plurality of lens patterns 411 are 35 μm and the average height ratio H/D is 40%. Although the diameter of a plurality of lens patterns 411 of FIG. 10A is larger than the size of the sub-pixel SP, the average height ratio H/D exceeds 30%, and thus, the bright portion and the dark portion irregularly appear depending on the pitch of the plurality of lens patterns 411, indicating that a sparkle phenomenon that looks like a spot occurs.

FIG. 10B is a diagram illustrating a sparkle phenomenon when the diameters D1 to Dn of a plurality of lens patterns 411 are 20 μm and the average height ratio H/D is 40%. Although the average height ratio H/D is less than 30%, the diameter of a plurality of lens patterns 411 is smaller than the size of the subpixel SP, and thus, it may be seen that a sparkle phenomenon in which the light portion and the dark portion appear irregularly depending on the pitches of the plurality of lens patterns 411 occurs.

In contrast, FIG. 10C is a diagram illustrating a sparkle phenomenon when the diameters D1 to Dn of a plurality of lens patterns 411 are 35 μm and the average height ratio H/D is 15%. Since the diameter of a plurality of lens patterns 411 of FIG. 10C is greater than the size of the sub-pixel SP and the average height ratio H/D is less than 30%, it may be seen that a sparkle phenomenon in which the light portion and the dark portion appear irregularly depending on the pitches of the plurality of lens patterns 411 is improved.

According to an aspect of the present disclosure, a plurality of lens patterns 411 may include a bottom surface 411a and a convex surface 411b.

In detail, referring to FIG. 5, a plurality of lens patterns 411 may include a bottom surface 411a and a convex surface 411b extending from an edge of the bottom surface 411a and having a predetermined curvature. The convex surface 411b may serve as a lens for refracting incident light since the convex surface 411b may have a focal length according to a radius of curvature.

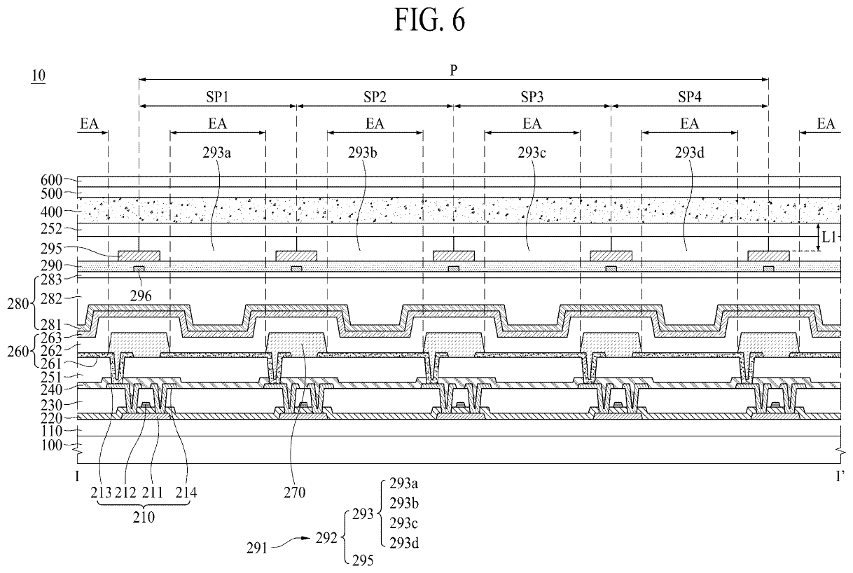

FIG. 6 is a cross-sectional view of a pixel according to another aspect of the present disclosure.

According to an aspect of the present disclosure, the light guide member 400 may contact the optical control layer 291.

Specifically, referring to FIG. 3, since no other layer is disposed between the light guide member 400 and the optical control layer 291, which is the color filter layer 292, the light guide member 400 and the optical control layer 291 may be in direct contact with each other. However, an aspect of the present disclosure is not limited thereto, and a planarization layer 252 may be further included between the light guide member 400 and the optical control layer 291 (shown in FIG. 6).

According to an aspect of the present disclosure, even when the planarization layer 252 is further included between the light guide member 400 and the optical control layer 291, when the distance between the upper surface of the black matrix 295 and the lower surface of the light guide member 400 is L1, L1 may be greater than 0 and equal to or less than 15 μm.

FIG. 7 is a cross-sectional view of a pixel according to another aspect of the present disclosure.

According to an aspect of the present disclosure, the optical control layer 291 may be a reflectance control layer 297. Specifically, the reflectance control layer 297 may include a first reflectance control layer 297a and a black matrix 295. More specifically, the organic light emitting display apparatus may include a reflectance control layer 297 instead of the color filter layer 292.

According to an aspect of the present disclosure, the first reflectance control layer 297a may be disposed on the organic light emitting element 260 and may be disposed on the same layer as the black matrix 295.

Here, the reflectance control layer 297 is a refractive index control layer, and the size of the spectrum may be greatly expanded by reducing the intensity of the diffraction dispersion spectrum of reflected light generated by the organic light emitting element 260 or re-dispersing the diffraction dispersion spectrum, and as a result, the occurrence of the radial rainbow mura phenomenon may be suppressed or minimized through mixing between adjacent spectra according to the diffraction order of the reflected light.

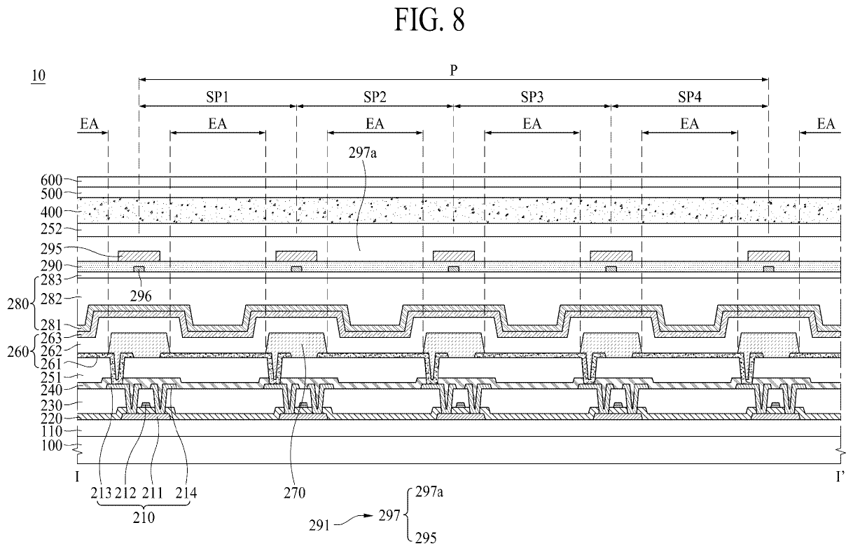

FIG. 8 is a cross-sectional view of a pixel according to another aspect of the present disclosure.

According to an aspect of the present disclosure, the organic light emitting display apparatus may further include a planarization layer 252 between the reflectance control layer 297 and a plurality of lens patterns 411 (shown in FIG. 8). However, an aspect of the present disclosure is not limited thereto, and the planarization layer 252 may not be disposed between the reflectance control layer 297 and a plurality of lens patterns 411 (shown in FIG. 7).

According to the present disclosure, the following advantageous effects may be obtained.

The organic light emitting display apparatus according to an aspect of the present disclosure may improve light extraction efficiency of light emitted from the light emitting layer, thereby realizing high efficiency and high luminance, thereby extending the life of the light emitting layer, and implementing low power as power consumption is reduced.

The organic light emitting display apparatus according to an aspect of the present disclosure may minimize or reduce the occurrence of a rainbow mura phenomenon due to reflection of external light.

The organic light emitting display apparatus according to an aspect of the present disclosure may minimize or reduce the occurrence of a sparkle phenomenon caused by a lens pattern.

In addition to the above-mentioned effects, other features and advantages of the present disclosure may be described below, or may be clearly understood by those of ordinary skill in the art to which the present disclosure belongs from such techniques and descriptions.

In addition to the above-mentioned effects, other features and advantages of the present disclosure will be described below or clearly understood by those of ordinary skill in the art to which the present disclosure belongs from such technology and description.

It will be apparent to those skilled in the art that the present disclosure described above is not limited by the above-described aspects and the accompanying drawings and that various substitutions, modifications and variations may be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. An organic light emitting display apparatus includes:
a substrate;
a plurality of organic light emitting elements disposed on the substrate;
an optical control layer disposed on the plurality of organic light emitting elements; and
a light guide member on the optical control layer;
wherein the optical control layer includes a black matrix disposed at a boundary of adjacent organic light emitting elements among the plurality of organic light emitting elements; and
wherein the light guide member includes:
a plurality of lens patterns having an irregular arrangement structure and a first refractive index; and
a refractive layer disposed on the plurality of lens patterns and having a second refractive index different from the first refractive index.

2. The organic light emitting display apparatus of claim 1, wherein the optical control layer further includes a color filter layer.

3. The organic light emitting display apparatus of claim 2, wherein the color filter layer includes a plurality of color filters having different colors, and
wherein the black matrix is disposed between two adjacent color filters.

4. The organic light emitting display apparatus of claim 1, wherein the light guide member contacts the optical control layer.

5. The organic light emitting display apparatus of claim 1, wherein the plurality of lens patterns are formed by an inkjet printing method.

6. The organic light emitting display apparatus of claim 1, wherein a distance between an upper surface of the black matrix and a lower surface of the light guide member is greater than 0 and less than or equal to 15 μm.

7. The organic light emitting display apparatus of claim 6, wherein the substrate includes a plurality of sub-pixels, and
wherein a diameter of each of the plurality of lens patterns is greater than a width of the plurality of sub-pixels.

8. The organic light emitting display apparatus of claim 6, when the ratio of the height to the diameter of each of the plurality of lens patterns is referred to as the height ratio, the average height ratio of the plurality of lens patterns is less than 30%.

9. The organic light emitting display apparatus of claim 1, wherein 10 to 30% of the plurality of lens patterns have a height ratio of at least 50%, and
wherein the height ratio is a ratio between a height and a diameter of each lens pattern.

10. The organic light emitting display apparatus of claim 1, wherein a difference between the first refractive index and the second refractive index ranges from 0.05 to 0.40.

11. The organic light emitting display apparatus of claim 1, wherein the plurality of lens patterns includes a portion having different diameters or different pitches.

12. The organic light emitting display apparatus of claim 1, wherein the plurality of lens patterns has a bottom surface and a convex surface extending from an edge of the bottom surface and having a predetermined curvature.

13. The organic light emitting display apparatus of claim 1, further comprising a planarization layer disposed between the optical control layer and the light guide member.

14. The organic light emitting display apparatus of claim 1, further comprising a touch electrode disposed between the organic light emitting element and the optical control layer.

15. The organic light emitting display apparatus of claim 1, wherein the optical control layer further includes a reflectance control layer.

16. An organic light emitting display apparatus includes:
a substrate including a plurality of sub-pixels;
a plurality of organic light emitting elements disposed in the plurality of sub-pixels;
a black matrix disposed between adjacent organic light emitting elements of the plurality of organic light emitting elements;
a plurality of lens patterns having a first refractive index; and
a refractive layer disposed on the plurality of lens patterns and having a second refractive index greater than the first refractive index,
wherein pitches between two adjacent lens patterns is different from one or more of a first direction, a second direction, and a diagonal direction between the first direction and the second direction, and
wherein each lens pattern has a diameter greater than a width of each sub-pixel.

17. The organic light emitting display apparatus of claim 16, further comprising a color filter layer disposed between two adjacent black matrices to correspond to each sub-pixel.

18. The organic light emitting display apparatus of claim 16, wherein each of the plurality of lens pattern covers a part of each of two adjacent black matrix.

19. The organic light emitting display apparatus of claim 16, further comprising a touch electrode disposed between the organic light emitting element and the optical control layer, and wherein each of the plurality of lens pattern covers a part of each of two adjacent touch electrode.

20. The organic light emitting display apparatus of claim 17, wherein the color filter layer is disposed on a same layer as the black matrix.

21. The organic light emitting display apparatus of claim 19, wherein the black matrix and the touch electrode overlap each other.
